(19) United States
(12) Patent Application Publication
(10) Pub. No.: US 2022/0223637 A1
(43) Pub. Date: Jul. 14, 2022

(54) SOLID-STATE IMAGING DEVICE AND MANUFACTURING METHOD THEREOF

(71) Applicant: SONY SEMICONDUCTOR SOLUTIONS CORPORATION, KANAGAWA (JP)

(72) Inventor: TOHRU TAKEDA, KANAGAWA (JP)

(21) Appl. No.: 17/609,960

(22) PCT Filed: May 20, 2020
(86) PCT No.: PCT/JP2020/019918

§ 371 Date: Nov. 9, 2021

(30) Foreign Application Priority Data
May 20, 2019 (JP) 2019-094645

(51) Int. Cl. H01L 27/146

(52) U.S. Cl. CPC H01L 27/1463; H01L 27/14685; H01L 27/14629; H01L 27/14627; H01L 27/14621

(57) ABSTRACT

There are provided a solid-state imaging device capable of effectively reducing color mixing and a manufacturing method thereof. A solid-state imaging device of the present disclosure includes a substrate and a photoelectric conversion unit provided in the substrate. In this solid-state imaging device, a plurality of protrusions are provided on the light incident surface of the substrate. Further, in this solid-state imaging device, the width of the protrusion becomes smaller as the distance from the center of the plurality of protrusions increases.

### TECHNICAL FIELD

The present disclosure relates to a solid-state imaging device and a manufacturing method thereof.

### BACKGROUND ART

A solid-state imaging device in which a light-receiving surface of a silicon layer having a photodiode is provided with a minute uneven structure to reduce the reflection of incident light has been proposed. Such a minute uneven structure is called a moth-eye structure. With the moth-eye structure, it is possible to reduce the reflection of incident light and improve the sensitivity of the solid-state imaging device.

### CITATION LIST

### Patent Literature

[PTL 1]

JP 2015-29054 A

[PTL 2]

JP 2017-108062 A

### SUMMARY

### Technical Problem

However, the moth-eye structure may scatter the light incident on each pixel to the adjacent pixels to cause color mixing between the pixels. Therefore, it has been proposed to reduce color mixing by providing an element separation portion or a light-shielding film in the area between the pixels, but these measures alone may not be sufficient to reduce color mixing.

Accordingly, the present disclosure provides a solid-state imaging device capable of effectively reducing color mixing and a manufacturing method thereof.

### Solution to Problem

A solid-state imaging device on the first aspect of the present disclosure includes a substrate and a photoelectric conversion unit provided in the substrate, wherein a plurality of protrusions are provided on a light incident surface of the substrate, and the width of the protrusion becomes smaller as the distance from the center of the plurality of protrusions increases. As a result, scattering of incident light can be suppressed by the protrusions, and color mixing can be effectively reduced.

Further, in the first aspect, each of the plurality of protrusions may have an annular shape in a plan view. As a result, scattering of incident light can be further suppressed by the annular protrusions, and color mixing can be effectively reduced.

Further, in the first aspect, the plurality of protrusions may have a concentric annular shape in a plan view. As a result, the incident light can be condensed in a point on the central axis by the protrusions having an annular shape, and color mixing can be effectively reduced.

Further, in the first aspect, each of the plurality of protrusions may have a circular or quadrangular annular shape in a plan view. As a result, the circular protrusion easily condenses the incident light, whereas the quadrangular protrusion can be easily formed.

Further, in the first aspect, a plurality of recesses may be provided alternately with the plurality of protrusions on the light incident surface of the substrate, and the width of the recess may become smaller as the distance from the center of the plurality of recesses increases. As a result, an optical element such as a zone plate can be realized by the protrusions and the recesses.

Further, in the first aspect, each of the plurality of recesses may have an annular shape in a plan view. As a result, scattering of incident light can be further suppressed by the annular recesses, and color mixing can be effectively reduced.

Further, the solid-state imaging device of the first aspect may further include a first material provided in the protrusions, and a second material that is provided between the protrusions and is different from the first material. As a result, it is possible to realize an optical element that utilizes the difference in light transmittance and refractive index between the first material and the second material.

Further, in the first aspect, the first material may serve as a material for a semiconductor region in the photoelectric conversion unit and also as a material for the protrusions. As a result, the protrusions can be formed by using a part of the photoelectric conversion unit.

Further, in the first aspect, the second material may include a film having a negative fixed charge. As a result, a dark current can be reduced in the protrusions by the film having a negative fixed charge.

Further, in the first aspect, the second material may include a first film having a negative fixed charge and a second film different from the first film. As a result, it is possible to fill the region between the protrusions with the film having a negative fixed charge and the other film.

Further, the solid-state imaging device of the first aspect may further include an element separation portion provided between the photoelectric conversion units adjacent to each other, wherein the second material includes an insulating material which is a material of the element separation portion. As a result, the protrusions can be formed in a step of forming the element separation portion.

Further, in the first aspect, the first material and the second material may have different light transmittances or refractive indexes from each other. As a result, a phase-type zone plate or an amplitude-type zone plate can be realized by the protrusions.

Further, the solid-state imaging device of the first aspect may further include a lens that condenses light and causes the light to fall on the protrusions, and a color filter layer provided between the lens and the protrusions, wherein the shape of the protrusions may differ for each type of color transmitted through the color filter layer. As a result, the performance of the protrusions can be changed according to the color.

Further, the solid-state imaging device of the first aspect may further include a wiring layer provided on a surface of the substrate opposite to the light incident surface, and a reflector that is provided between the photoelectric conversion unit and the wiring layer and reflects light from the photoelectric conversion unit. As a result, it is possible to prevent the light condensed by the protrusions from being incident on the wiring layer.

Further, in the first aspect, the surface of the reflector on the photoelectric conversion portion side may have a recessed shape. As a result, it is possible to prevent the reflected light from the reflector from being scattered to the adjacent pixels.

Further, the solid-state imaging device of the first aspect may further include a memory unit that is provided between the photoelectric conversion unit and a surface of the substrate opposite to the light incident surface and that holds a charge from the photoelectric conversion unit. As a result, even if the memory unit is provided on the opposite side of the lens with respect to the photoelectric conversion unit, the protrusions can prevent the incident light from being incident on the memory unit.

Further, in the first aspect, the plurality of protrusions have a concentric annular shape having a central axis at the same position in a plan view, and the memory unit may be provided at a position not overlapping the central axis. As a result, even if the incident light is condensed in a point on the central axis by the protrusions, the incident light can be prevented from being incident on the memory unit.

A solid-state imaging device of the second aspect of the present disclosure includes a lens that condenses light, a photoelectric conversion unit that converts light from the lens into a charge, and a light condensing unit that is provided between the lens and the photoelectric conversion unit and condenses light from the lens on the photoelectric conversion unit. As a result, the incident light can be condensed by the light condensing unit, and color mixing can be effectively reduced.

Further, in the second aspect, the photoelectric conversion unit is provided in a substrate, and the light condensing unit may condense light from the lens on the photoelectric conversion unit by a plurality of protrusions provided on a light incident surface of the substrate. As a result, the light condensing action of the light condensing unit can be realized by the protrusions.

A method for manufacturing a solid-state imaging device according to the third aspect of the present disclosure includes: forming a photoelectric conversion unit in the substrate, and forming a plurality of protrusions on a light incident surface of the substrate so that the width of the protrusion becomes smaller as the distance from the center of the plurality of protrusions increases. As a result, scattering of incident light can be suppressed by the protrusions, and color mixing can be effectively reduced.

### BRIEF DESCRIPTION OF DRAWINGS

FIG. 1 is a block diagram showing the configuration of a solid-state imaging device according to a first embodiment.

FIG. 2 is a cross-sectional view showing the structure of the solid-state imaging device of the first embodiment.

FIG. 3 is a plan view showing the structure of the solid-state imaging device of the first embodiment.

FIG. 4 is a cross-sectional view (1 of 2) showing a method for manufacturing the solid-state imaging device of the first embodiment.

FIG. 5 is a cross-sectional view (2 of 2) showing a method for manufacturing the solid-state imaging device of the first embodiment.

FIG. 6 is a cross-sectional view showing the shape of the zone plate of the first embodiment.

FIG. 7 is a cross-sectional view for comparing the solid-state imaging device of a comparative example with the solid-state imaging device of the first embodiment.

FIG. 8 is a cross-sectional view for explaining the operation of the zone plate of the first embodiment.

FIG. 9 is a cross-sectional view (1 of 3) showing a method for forming the zone plate of the first embodiment.

FIG. 10 is a cross-sectional view (2 of 3) showing a method for forming the zone plate of the first embodiment.

FIG. 11 is a cross-sectional view (3 of 3) showing a method for forming the zone plate of the first embodiment.

FIG. 12 is a plan view showing an example of the zone plate of the first embodiment.

FIG. 13 is a cross-sectional view showing another example of the zone plate of the first embodiment.

FIG. 14 is a cross-sectional view showing another example of the zone plate of the first embodiment.

FIG. 15 is a plan view showing another example of the zone plate of the first embodiment.

FIG. 16 is a cross-sectional view showing the structure of the solid-state imaging device of a second embodiment and the solid-state imaging device of a modification example thereof.

FIG. 17 is a cross-sectional view showing the structure of the solid-state imaging device of a third embodiment.

FIG. 18 is a cross-sectional view showing the shape of a zone plate of the fourth embodiment.

FIG. 19 is a cross-sectional view showing the shape of a light condensing unit of modification examples of the first to fourth embodiments.

### DESCRIPTION OF EMBODIMENTS

Hereinafter, embodiments of the present disclosure will be described with reference to the drawings.

### First Embodiment

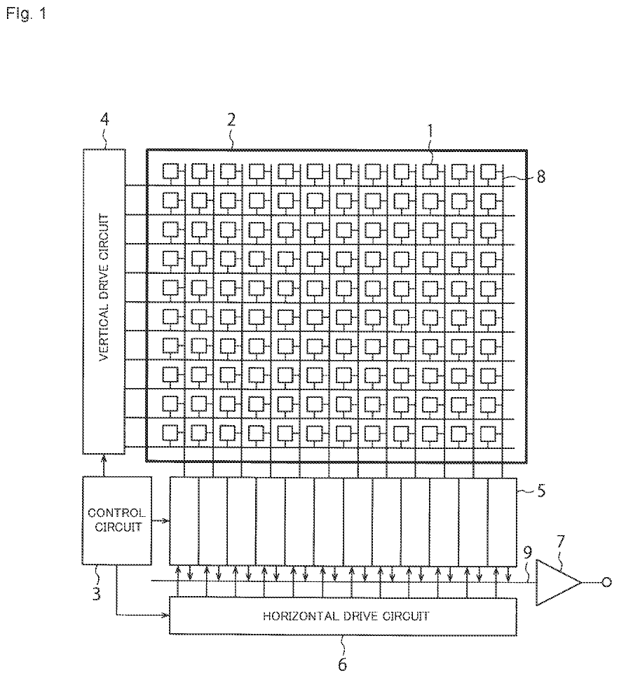

FIG. 1 is a block diagram showing a configuration of a solid-state imaging device of the first embodiment.

The solid-state imaging device of FIG. 1 is a CMOS (Complementary Metal Oxide Semiconductor) type solid-state imaging device, and has a pixel region 2 having a plurality of pixels 1, a control circuit 3, a vertical drive circuit 4, a plurality of column signal processing circuit 5, a horizontal drive circuit 6, an output circuit 7, a plurality of vertical signal lines 8, and a horizontal signal line 9.

Each pixel 1 is configured of a photoelectric conversion unit including a photodiode, a plurality of pixel transistors, and the like. Examples of pixel transistors are four MOS transistors: a transfer transistor, a reset transistor, an amplifier transistor, and a selection transistor. However, the pixel transistors may be three transistors excluding the selection transistor.

The pixel region 2 has a plurality of pixels 1 that are regularly arranged in a two-dimensional array on a substrate. The pixel region 2 includes an effective pixel region that receives light, performs photoelectric conversion, and amplifies and outputs a signal charge generated by photoelectric conversion, and a black reference pixel region (not shown) for outputting optical black that is the basis of a black level. Generally, the black reference pixel region is arranged in the outer peripheral portion of the effective pixel region.

The control circuit 3 generates various signals that serve as reference for the operation of the vertical drive circuit 4, the column signal processing circuit 5, the horizontal drive circuit 6, and the like on the basis of a vertical synchronization signal, a horizontal synchronization signal, and a master clock. The signals generated by the control circuit 3 are, for example, clock signals or control signals, and are input to the vertical drive circuit 4, the column signal processing circuit 5, the horizontal drive circuit 6, and the like.

The vertical drive circuit 4 includes, for example, a shift register, and sequentially selects and scans each pixel 1 in the pixel region 2 in the vertical direction in units of rows. The vertical drive circuit 4 further supplies a pixel signal based on the signal charge generated by each pixel 1 according to the received light quantity to the column signal processing circuit 5 through the vertical signal line 8.

The column signal processing circuit 5 is arranged for each column of pixels 1 in the pixel region 2, and performs signal processing of the signal output from the pixel 1 for one row on the basis of the signal from the black reference pixel region. Examples of signal processing are denoising and signal amplification. At the output stage of the column signal processing circuits 5, a horizontal selection switch (not shown) is provided between the column signal processing circuits and the horizontal signal line 9.

The horizontal drive circuit 6 includes, for example, a shift register, sequentially selects each of the column signal processing circuits 5 by sequentially outputting horizontal scanning pulses, and outputs pixel signals from each of the column signal processing circuits 5 to the horizontal signal line 9.

The output circuit 7 performs signal processing on the signals sequentially supplied from each of the column signal processing circuits 5 through the horizontal signal line 9, and outputs the signals subjected to signal processing.

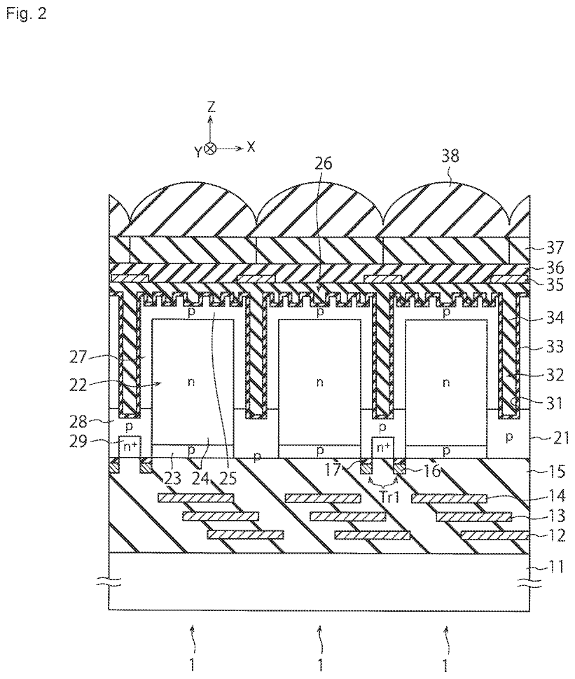

FIG. 2 is a cross-sectional view showing the structure of the solid-state imaging device of the first embodiment. FIG. 2 shows a vertical cross section of the pixel region 2 of FIG. 1.

The solid-state imaging device of the present embodiment includes a support substrate 11, a plurality of wiring layers 12, 13, and 14, an interlayer insulating film 15, and a gate electrode 16 and a gate insulating film 17 included in each transfer transistor Tr1.

The solid-state imaging device of the present embodiment further includes a substrate 21, a plurality of photoelectric conversion units 22 in the substrate 21, a p-type semiconductor region 23, an n-type semiconductor region 24 and a p-type semiconductor region 25 included in each photoelectric conversion unit 22, a zone plate 26 for each photoelectric conversion unit 22, a pixel separation layer 27 in the substrate 21, a p-well layer 28, and a plurality of floating diffusion portions 29.

The solid-state imaging device of the present embodiment further includes a groove 31, an element separation portion 32 provided in the groove 31, a fixed charge film (a film having a negative fixed charge) 33 and an insulating film 34 included in the element separation portion 32 and the like, a plurality of light-shielding films 35, a flattening film 36, a plurality of color filter layers 37, and a plurality of on-chip lenses 38.

FIG. 2 shows X-axis, Y-axis, and Z-axis that are perpendicular to each other. The X and Y directions correspond to the lateral direction, the Z direction corresponds to the upward direction, and the −Z direction corresponds to the downward direction. The −Z direction may or may not exactly coincide with the direction of gravity.

The substrate 21 is, for example, a semiconductor substrate such as a silicon (Si) substrate. In FIG. 2, the surface of the substrate 21 in the −Z direction is the front surface of the substrate 21, and the surface of the substrate 21 in the Z direction is the surface of the back side (back surface) of the substrate 21. Since the solid-state imaging device of the present embodiment is a back-illuminated type, the color filter layers 37 and the on-chip lenses 38 are provided on the back side of the substrate 21, and are located above the substrate 21 in FIG. 2. The back surface of the substrate 21 is the light incident surface of the substrate 21. Meanwhile, the wiring layers 12 to 14 are provided on the front side of the substrate 21, and are located below the substrate 21 in FIG. 2. The thickness of the substrate 21 is, for example, 1 μm to 6 μm.

The photoelectric conversion unit 22 is provided in the substrate 21 for each pixel 1. FIG. 2 illustrates three photoelectric conversion units 22 for three pixels 1. Each photoelectric conversion unit 22 includes a p-type semiconductor region 23, an n-type semiconductor region 24, and a p-type semiconductor region 25, which are sequentially formed in the substrate 21 from the front side to the back side of the substrate 21. In the photoelectric conversion unit 22, the main photodiode is realized by a pn junction between the p-type semiconductor region 23 and the n-type semiconductor region 24 and a pn junction between the n-type semiconductor region 24 and the p-type semiconductor region 25, and the photodiode converts light into an electric charge. The photoelectric conversion unit 22 receives the light, which is incident on the on-chip lens 38, through the color filter layer 37, generates a signal charge according to the quantity of the received light, and accumulates the generated signal charge in the n-type semiconductor region 24.

The zone plate 26 is provided for each pixel 1 between the photoelectric conversion unit 22 and the flattening film 36. FIG. 2 illustrates three zone plates 26 for three pixels 1. Each zone plate 26 is realized by a plurality of annular portions having an annular shape when viewed from the Z direction or the −Z direction, and these annular portions alternately include a plurality of first annular portions including portions of the p-type semiconductor region 25, and a plurality of second annular portions including portions of the fixed charge film 33 and the insulating film 34. FIG. 2 shows the uneven shape of the zone plate 26, and this uneven shape shows the cross section of the first annular portions and the second annular portions. This uneven shape has a plurality of recesses recessed in the −Z direction (photoelectric conversion unit 22 side) with respect to the back surface of the substrate 21, and a plurality of protrusions protruding in the Z direction (opposite side of the photoelectric conversion unit 22) with respect to the bottom surface of these recesses. Conversely, these recesses are recessed in the −Z direction with respect to the top surface of the protrusions. The material forming the p-type semiconductor region 25 of the present disclosure is an example of the first material, and the material forming the fixed charge film 33 and the insulating film 34 of the present disclosure is an example of the second material different from the first material.

The shape of each annular portion is, for example, a circular annular shape in a plan view. However, the annular shape, which is the shape of each annular portion, may be a shape other than a circle as long as it is a closed curve shape. For example, the shape of each annular portion may be a quadrangular annular shape such as a square, a rectangle, a rhombus, or a parallelogram in a plan view. The details of the shape of each annular portion will be described hereinbelow.

The annular portions of the present embodiment are configured to form a zone plate 26 that condenses light. Therefore, in the present embodiment, the light from the on-chip lens 38 is condensed in the photoelectric conversion unit 22 by the zone plate 26. This makes it possible to reduce color mixing between the pixels 1. The zone plate 26 of the present embodiment has an uneven shape (uneven surface) formed at the boundary between the first material which is the material of the first annular portion and the second material which is the material of the second annular portion. The properties of the zone plate 26 of the present embodiment are determined by the dimensions of the uneven shape, properties of the first material under the zone plate 26, properties of the second material above the zone plate 26, and the like. The zone plate 26 of the present disclosure is an example of a light condensing unit.

The pixel separation layer 27 is a p-type semiconductor region provided between the photoelectric conversion units 22 adjacent to each other. The p-well layer 28 is a p-type semiconductor region provided on the front side of the substrate 21 with respect to the pixel separation layer 27. The floating diffusion portion 29 is an n+ type semiconductor region provided on the front side of the substrate 21 with respect to the p-well layer 28. The floating diffusion portion 29 is formed by injecting n-type impurities into the p-well layer 28 at a high concentration.

The p-type semiconductor region and the n-type semiconductor region in the substrate 21 of the present embodiment may be interchanged with each other. That is, the p-type semiconductor region 23, the p-type semiconductor region 25, the pixel separation layer 27, and the p-well layer 28 may be changed into the n-type semiconductor regions, and the n-type semiconductor region 24 and the floating diffusion portion 29 may be changed into the p-type semiconductor regions.

The groove 31 has a shape extending from the back surface of the substrate 21 in the depth direction (−Z direction), and is provided between the photoelectric conversion units 22 adjacent to each other, similarly to the pixel separation layer 27. The groove 31 is formed by forming a recess in the pixel separation layer 27 by etching. The groove 31 of the present embodiment reaches the p-well layer 28, but does not reach the floating diffusion portion 29.

The element separation portion 32 includes the fixed charge film 33 and the insulating film 34, which are sequentially formed in the groove 31. The fixed charge film 33 is formed on the side surface and the bottom surface of the groove 31. The insulating film 34 is embedded in the groove 31 with the fixed charge film 33 being interposed therebetween.

The fixed charge film 33 is a film having a negative fixed charge, serves a material of the element separation portion 32, and is inserted into the recesses of the uneven shape of the zone plate 26. Generally, in a solid-state imaging device, electric charges may be generated from minute defects existing at the interface of the substrate 21 even in a state where there is no incident light and no signal charges. The generated charges cause noise called dark current. However, the film having a negative fixed charge has an effect of suppressing the generation of such a dark current. Therefore, according to the present embodiment, the dark current can be reduced by the fixed charge film 33. Since the fixed charge film 33 of the present embodiment is arranged not only in the element separation portion 32 but also in the vicinity of the zone plate 26, not only the dark current can be reduced in the element separation portion 32 but the dark current can be reduced in the zone plate 26 as well. The fixed charge film 33 of the present embodiment is formed on the entire back surface of the substrate 21.

The fixed charge film 33 is preferably formed of a material that can generate a fixed charge and strengthen the pinning when formed on a substrate 21 such as a silicon substrate. An example of such a fixed charge film 33 is an insulating film such as a high-refractive-index material film or a high-dielectric film. The fixed charge film 33 of the present disclosure is an example of the first film and the insulating material contained in the second material.

The fixed charge film 33 is, for example, an oxide film or a nitride film including at least one metal element of hafnium (HO, aluminum (Al), zirconium (Zr), tantalum (Ta), and titanium (Ti). A method for forming the fixed charge film 33 is, for example, CVD (Chemical Vapor Deposition), sputtering, ALD (Atomic Layer Deposition), or the like. When ALD is used, a silicon oxide film, which is a film for reducing the interface state, can also be formed with a film thickness of about 1 nm in the step of forming the fixed charge film 33. Other examples of the fixed charge film 33 include oxides and nitrides of at least one metal element among lanthanum (La), praseodymium (Pr), cerium (Ce), neodymium (Nd), promethium (Pm), samarium (Sm), europium (Eu), gadolinium (Gd), terbium (Tb), dysprosium (Dy), holmium (Ho), thulium (Tm), ytterbium (Yb), lutetium (Lu), and yttrium (Y). Further, the fixed charge film 33 may be a hafnium oxynitride film or an aluminum oxynitride film.

Silicon (Si) or nitrogen (N) may be added to the fixed charge film 33 as long as the insulating property is not impaired. This makes it possible to improve the heat resistance of the fixed charge film 33 and the ability to prevent ion injection.

In the present embodiment, the element separation portion 32 and the zone plate 26 are realized by the fixed charge film 33 or the like, and an inversion layer is formed on the surface in contact with the fixed charge film 33. Therefore, since the interface of the substrate 21 is pinned by the inversion layer, the generation of dark current is suppressed. In the present embodiment, since the groove 31 is formed on the substrate 21, physical damage may occur on the side surface and bottom surface of the groove 31, and pinning detachment may occur in the peripheral portion of the groove 31. However, in the present embodiment, the pinning detachment can be prevented by forming the fixed charge film 33 on the side surface and bottom surface of the groove 31. This also applies to the physical damage that occurs when forming the zone plate 26.

The insulating film 34 is used together with the fixed charge film 33 as a material for the element separation portion 32, and the insulating film 34 and the fixed charge film 33 are both inserted into the recesses of the uneven shape of the zone plate 26. The insulating film 34 of the present disclosure is an example of the second film and the insulating material contained in the second material. The insulating film 34 is preferably formed of a material having a refractive index different from that of the fixed charge film 33. Examples of such an insulating film 34 are a silicon oxide film, a silicon nitride film, a silicon oxynitride film, a resin film, and the like. Further, the insulating film 34 may be a film having no positive fixed charge or a film having a small positive fixed charge. The insulating film 34 of the present embodiment is formed on the entire back surface of the substrate 21.

In the present embodiment, the groove 31 is filled with the insulating film 34 or the like, so that the photoelectric conversion units 22 are separated from each other by the insulating film 34 or the like. Therefore, the signal charge is less likely to leak from each pixel 1 to the adjacent pixel 1, so that when a signal charge exceeding a saturated charge amount is generated, it is possible to reduce the leakage of a signal charge from the photoelectric conversion unit 22 overflowing with the signal charge to the adjacent photoelectric conversion unit 22. As a result, color mixing between the pixels 1 can be suppressed.

Since the fixed charge film 33 and the insulating film 34 of the present embodiment are used as the materials of the element separation portion 32 and are embedded in the recesses of the uneven shape of the zone plate 26, the zone plate 26 can also be formed in the step of forming the element separation portion 32. The fixed charge film 33 and the insulating film 34 on the zone plate 26 can play the role of an antireflection film due to the difference in the refractive index. This makes it possible to suppress the reflection of the light incident on the back surface of the substrate 21. In the present embodiment, such an effect can be obtained by forming the annular portions (second annular portions) on the zone plate 26 by using the fixed charge film 33 and the insulating film 34.

The light-shielding film 35 is formed in a predetermined region on the insulating film 34 formed on the back surface of the substrate 21, and has an effect of blocking light from the on-chip lens 38. In the pixel region 2, the light-shielding film 35 is formed in a grid pattern so that the photoelectric conversion unit 22 opens toward the on-chip lens 38, and specifically, the light-shielding film is formed on the element separation portion 32. The light-shielding film 35 is formed of a material that blocks light, and includes an element such as tungsten (W), aluminum (Al), or copper (Cu).

The flattening film 36 is formed on the entire surface of the insulating film 34 so as to cover the light-shielding film 35, whereby the surface on the back surface of the substrate 21 is flattened. The flattening film 36 is, for example, an organic film such as a resin film.

The color filter layer 37 is formed on the flattening film 36 for each pixel 1. For example, the color filter layers 37 for red (R), green (G), and blue (B) are arranged above the photoelectric conversion unit 22 of the red, green, and blue pixels 1, respectively. Further, these color filter layers 37 may include a color filter layer 37 for infrared light above the photoelectric conversion unit 22 of the infrared light pixel 1. Each color filter layer 37 has a property of being able to transmit light having a predetermined wavelength, and the light transmitted through each color filter layer 37 is incident on the photoelectric conversion unit 22 via the zone plate 26.

The on-chip lens 38 is formed on the color filter layer 37 for each pixel 1. Each on-chip lens 38 has a property of condensing the incident light, and the light condensed by each on-chip lens 38 falls on the photoelectric conversion unit 22 through the color filter layer 37 and the zone plate 26.

The support substrate 11 is provided on the front side of the substrate 21 with the interlayer insulating film 15 being interposed therebetween, and is provided to ensure the strength of the substrate 21. The support substrate 11 is, for example, a semiconductor substrate such as a silicon (Si) substrate.

The wiring layers 12 to 14 are provided in the interlayer insulating film 15 provided on the front side of the substrate 21 to form a multilayer wiring structure. The multilayer wiring structure of the present embodiment includes three wiring layers 12 to 14, but may include four or more wiring layers. Each of the wiring layers 12 to 14 includes various wires, and pixel transistors such as the transfer transistors Tr1 are driven by using these wires. The wiring layers 12 to 14 are metal layers including elements such as tungsten, aluminum, and copper. The interlayer insulating film 15 is, for example, an insulating film such as a silicon oxide film.

The gate electrode 16 of each transfer transistor Tr1 is provided under the p-well layer 28 between the p-type semiconductor region 23 and the floating diffusion portion 29 with the gate insulating film 17 being interposed between the gate electrode and the p-well layer. Each transfer transistor Tr1 can transfer the signal charge in the photoelectric conversion unit 22 to the floating diffusion portion 29. The gate electrode 16 and the gate insulating film 17 are provided in the interlayer insulating film 15.

In the solid-state imaging device of the present embodiment, light is radiated from the back side of the substrate 21, and the light is incident on the on-chip lens 38. The light incident on the on-chip lens 38 is condensed by the on-chip lens 38 and incident on the photoelectric conversion unit 22 through the color filter layer 37 and the zone plate 26. The photoelectric conversion unit 22 converts this light into an electric charge by photoelectric conversion to generate a signal charge. The signal charge is output as a pixel signal via the vertical signal line 8 in the wiring layers 12 to 14 provided on the front side of the substrate 21.

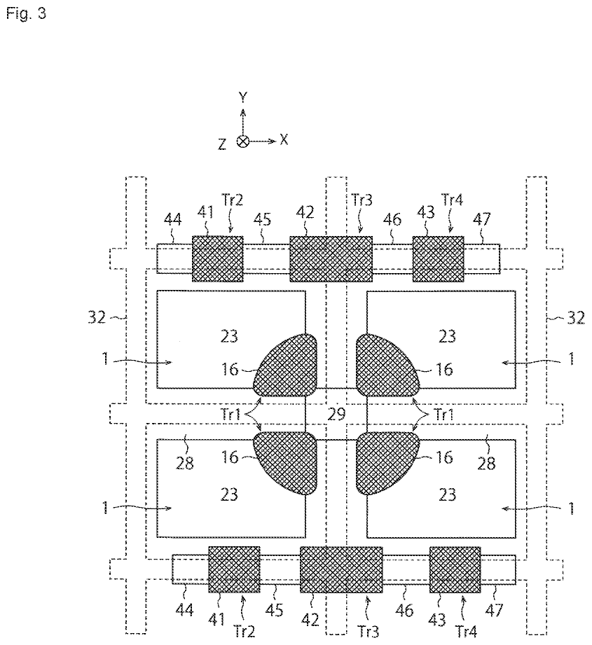

FIG. 3 is a plan view showing the structure of the solid-state imaging device of the first embodiment. FIG. 3 shows a view of the planar structure of the pixel region 2 of FIG. 1 from the −Z direction.

In FIG. 3, four pixels 1 share a pixel transistor. FIG. 3 shows four transfer transistors Tr1, two reset transistors Tr2, two amplifier transistors Tr3, and two selection transistors Tr4 shared by these pixels 1.

The transfer transistor Tr1 includes the gate electrode 16 provided on the front side of the substrate 21 with the gate insulating film 17 interposed therebetween (FIG. 2). Similarly, the reset transistor Tr2, the amplifier transistor Tr3, and the selection transistor Tr4 each include gate electrodes 41, 42, and 43, respectively, provided on the front side of the substrate 21 with a gate insulating film (not shown) interposed therebetween. The solid-state imaging device of the present embodiment further includes source-drain regions 44, 45, 46, and 47 for the reset transistors Tr2, the amplifier transistors Tr3, and the selection transistors Tr4 in the substrate 21. These four types of transistors function as pixel transistors of the solid-state imaging device.

FIG. 3 shows the p-type semiconductor region 23 provided in each of the four pixels 1, the p-well layers 28 interposed between these p-type semiconductor regions 23, and the floating diffusion portion 29 shared by the four pixels 1. In FIG. 3, the position of the element separation portion 32 is further indicated by a dotted line. The gate electrodes 16 of the four transfer transistors Tr1 are each arranged so as to straddle the corresponding p-type semiconductor region 23 and the floating diffusion portion 29. These transfer transistors Tr1 can transfer the signal charge in the corresponding photoelectric conversion unit 22 to the floating diffusion portion 29.

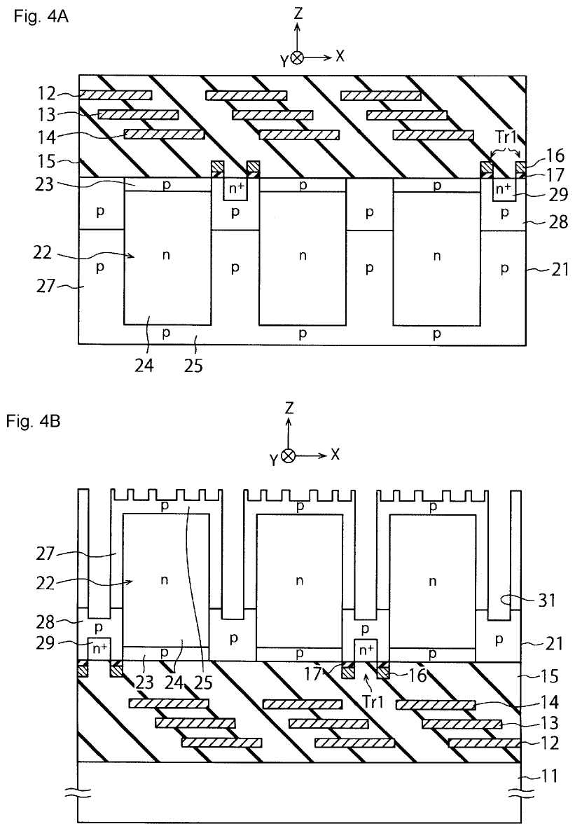

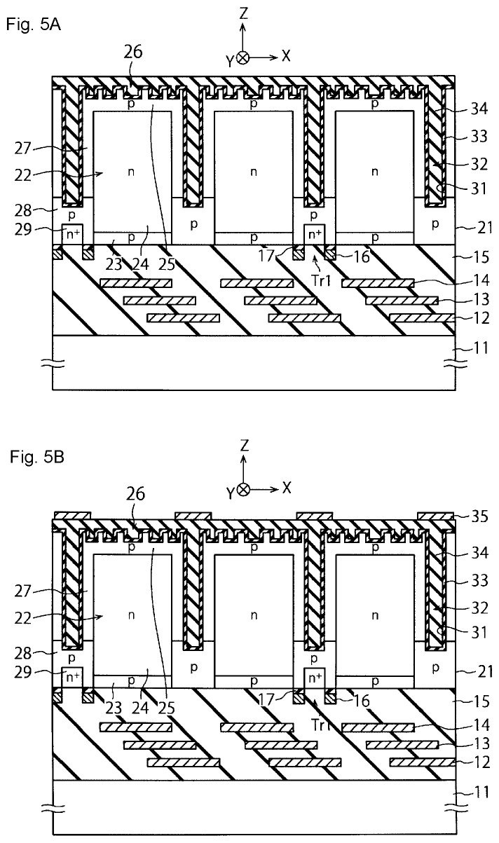

FIGS. 4 and 5 are cross-sectional views showing a method for manufacturing the solid-state imaging device of the first embodiment.

First, as shown in A of FIG. 4, the p-type semiconductor regions 23, the n-type semiconductor regions 24, the p-type semiconductor regions 25, the pixel separation layers 27, the p-well layers 28, the floating diffusion portions 29, the gate insulating films 17, the gate electrodes 16, and the like are formed in the substrate 21 or on the substrate 21. At this stage, the gate insulating films, the gate electrodes 41 to 43, and the source-drain regions 44 to 47 for the reset transistors Tr2, the amplifier transistors Tr3, and the selection transistors Tr4, are also formed. In this way, the photoelectric conversion units 22 and the pixel transistors are formed. Next, as shown in A of FIG. 4, the interlayer insulating film 15 and the wiring layers 12 to 14 are alternately formed on the front side of the substrate 21. The step shown in A in FIG. 4 is executed with the front side of the substrate 21 facing up and the back side of the substrate 21 facing down.

Next, as shown in B of FIG. 4, the support substrate 11 is adhered to the front side of the substrate 21 with the interlayer insulating film 15 interposed therebetween, and then the substrate 21 is turned upside down. Here, B of FIG. 4 shows a state in which the front side of the substrate 21 faces downward and the back side of the substrate 21 faces upward.

Next, as shown in B of FIG. 4, after the substrate 21 is thinned from the back surface, grooves 31 having a predetermined depth are formed in the substrate 21 by etching. The groove 31 is formed in the pixel separation layer 27 from the back surface of the substrate 21. The depth of the groove 31 is preferably 0.2 μm or more and more preferably 1.0 μm or more from the back surface of the substrate 21 in consideration of spectral characteristics. Further, the width of the groove 31 is preferably 0.02 μm or more in consideration of spectral characteristics. By setting a large width of the groove 31, it becomes easy to process the groove 31, but the larger the width of the groove 31, the lower the spectral characteristics and the saturated charge amount, so it is more desirable to set the width of the groove 31 to about 0.02 μm. The groove 31 of the present embodiment is formed to a depth that reaches the p-well layer 28 and does not reach the floating diffusion portion 29 or the source-drain regions 44 to 47.

Next, as shown in B of FIG. 4, the back surface of the substrate 21 is processed by etching to form the first annular portions of the zone plate 26 in the p-type semiconductor regions 25. The first annular portions of the zone plate 26 are formed after the formation of the grooves 31 in the present embodiment, but may be formed before the formation of the grooves 31. Details of the formation process of the zone plate 26 will be described hereinbelow.

Next, as shown in A of FIG. 5, a fixed charge film 33 and an insulating film 34 are sequentially formed on the back surface of the substrate 21. As a result, the fixed charge film 33 is formed on the side surface and the bottom surface of the grooves 31 and on the side surface and the bottom surface of the gaps between the first annular portions of the zone plate 26. Further, the insulating film 34 is embedded in the grooves 31 with the fixed charge film 33 interposed therebetween, and is also embedded in the gaps between the first annular portions of the zone plate 26 with the fixed charge film 33 interposed therebetween. In this way, the element separation portion 32 is formed in the groove 31, and the zone plate 26 including the plurality of first annular portions and the plurality of second annular portions alternately is formed on the photoelectric conversion units 22. The second annular portion is formed in the gap between the first annular portions by the fixed charge film 33 and the insulating film 34. The fixed charge film 33 is formed by, for example, CVD, sputtering, or ALD. The insulating film 34 is formed by, for example, CVD.

Next, as shown in B of FIG. 5, the light-shielding film 35 is formed in a predetermined region on the insulating film 34 formed on the back surface of the substrate 21. The light-shielding film 35 is formed, for example, by forming a material layer of the light-shielding film 35 on the insulating film 34 and patterning the material layer in a predetermined shape. The light-shielding film 35 of the present embodiment is formed above the element separation portion 32, and specifically, above the element separation portion 32 extending in the Y direction between the pixels 1 adjacent to each other in the X direction, or above the element separation portion 32 extending in the X direction between the pixels 1 adjacent to each other in the Y direction.

After that, the flattening film 36 is formed on the insulating film 34 with the light-shielding film 35 interposed therebetween, a color filter layer 37 is formed on the flattening film 36, and on-chip lenses 38 are formed on the color filter layer 37. In this way, the solid-state imaging device shown in FIG. 2 is manufactured.

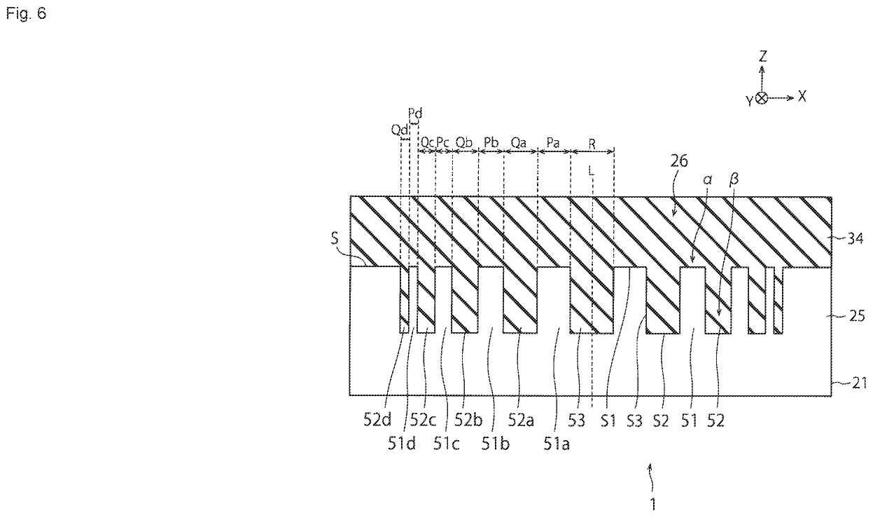

FIG. 6 is a cross-sectional view showing the shape of the zone plate 26 of the first embodiment. FIG. 6 shows a vertical cross section of the zone plate 26 as in FIG. 2.

The zone plate 26 of the present embodiment is realized by a plurality of annular portions having an annular shape when viewed from the Z direction or the −Z direction. These annular portions alternately include a plurality of first annular portions 51 including the p-type semiconductor region 25 and a plurality of second annular portions 52 including the fixed charge film 33 and the insulating film 34. In FIG. 6, the fixed charge film 33 is not shown in order to make the drawing easier to view. The shape and arrangement of the fixed charge film 33 are shown in FIG. 2 and the like. The zone plate 26 of the present embodiment further includes a non-annular portion 53 having a non-annular shape when viewed from the Z direction or the −Z direction on the inside of the first and second annular portions 51 and 52. The non-annular portion 53 of the present embodiment includes the fixed charge film 33 and the insulating film 34. The material forming the p-type semiconductor region 25 of the present disclosure is an example of the first material, and the material forming the fixed charge film 33 and the insulating film 34 of the present disclosure is an example of the second material different from the first material.

FIG. 6 shows the uneven shape of the zone plate 26, and in this uneven shape, the cross sections of the first annular portion 51, the second annular portion 52, and the non-annular portion 53 are shown. The shape of the first annular portions 51 and the second annular portions 52 is, for example, a circular or quadrangular annular shape. The shape of the non-annular portion 53 is, for example, a circle or a quadrangle. The material of the p-type semiconductor region 25 also serves as a material of the photoelectric conversion unit 22 and a material facing the uneven shape of the zone plate 26. Similarly, the fixed charge film 33 also serves as a material of the element separation portion 32 and a material facing the uneven shape of the zone plate 26.

FIG. 6 further shows the back surface S of the substrate 21. In the present embodiment, a plurality of annular recesses ß and one non-annular recess ß are formed by etching the back surface S of the substrate 21, thereby forming the first annular portions 51 between these recesses ß. Then, the fixed charge film 33 and the insulating film 34 are embedded in the recesses ß, thereby forming the second annular portions 52 and the non-annular portion 53 in the recesses ß. Therefore, the uneven shape of the zone plate 26 in FIG. 6 has a plurality of recesses ß recessed in the −Z direction with respect to the back surface S of the substrate 21, and a plurality of protrusions α protruding in the Z direction with respect to a predetermined surface, specifically, a bottom surface S2 of these recesses ß. In other words, the recess ß is recessed in the −Z direction with respect to a top surface 51 of the protrusion α. The zone plate 26 has an uneven shape including the top surface 51 of the protrusions α, the bottom surface S2 of the recesses ß, and a side surface S3 between the top surface 51 and the bottom surface S2. Each protrusion α has the top surface 51 and a side surface S3, each recess ß has the bottom surface S2 and the side surface S3, and the side surface S2 is shared by the protrusion α and the recess ß.

FIG. 6 illustrates four first annular portions 51a to 51d as the first annular portions 51 and four second annular portions 52a to 52d as the second annular portions 52. The first annular portions 51a to 51d are arranged so that the distance from the center of these annular portions increases in the order of 51a, 51b, 51c, 51d. Similarly, the second annular portions 52a to 52d are arranged so that the distance from the center of these annular portions increases in the order of 52a, 52b, 52c, 52d.

FIG. 6 further shows the widths Pa to Pd of the first annular portions 51a to 51d, the widths Qa to Qd of the second annular portions 52a to 52d, and the width R of the non-annular portion 53. In the present embodiment, the widths Pa to Pd of the first annular portions 51a to 51d are set so as to become smaller as the distance from the center of these annular portions increases (that is, Pa>Pb>Pc>Pd). Further, the widths Qa to Qd of the second annular portions 52a to 52d are set so as to become smaller as the distance from the center of these annular portions increases (that is, Qa>Qb>Qc>Qd). Further, the width R of the non-annular portion 53 is set to be larger than the width Qa of the innermost second annular portion 52a (R>Qa). As a result, these annular portions and non-annular portion can function as the zone plate 26 that condenses light. The zone plate 26 of the present disclosure is an example of a light condensing unit.

The first annular portions 51a to 51d and the second annular portions 52a to 52d of the present embodiment have a concentric annular shape having a central axis L at the same position. For example, when the shapes of the first and second annular portions 51 and 52 are circular annular shapes, the first and second annular portions 51 and 52 have a concentric shape centered on the central axis L. In the present embodiment, the non-annular portion 53 also has a shape centered on the central axis L. Therefore, the zone plate 26 of the present embodiment can condense light at a point on the central axis L.

Examples of the zone plate 26 include a phase-type zone plate realized by using the difference in the refractive index of light between the first annular portion 51 and the second annular portion 52, and an amplitude-type zone plate realized by using the difference in light transmittance between the first annular portion 51 and the second annular portion 52. The preferable width and height of the first and second annular portions 51 and 52 vary depending on the type of the zone plate 26 and the wavelength of light to be handled. Details of the phase-type zone plate and the amplitude-type zone plate will be described hereinbelow.

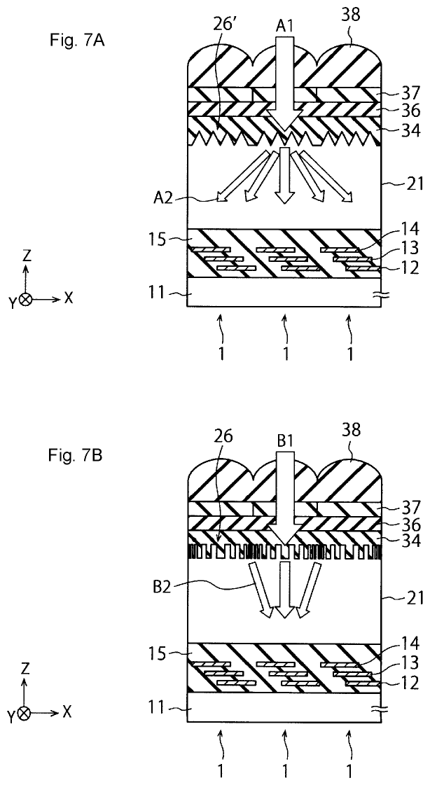

FIG. 7 is a cross-sectional view for comparing a solid-state imaging device of a comparative example with the solid-state imaging device of the first embodiment.

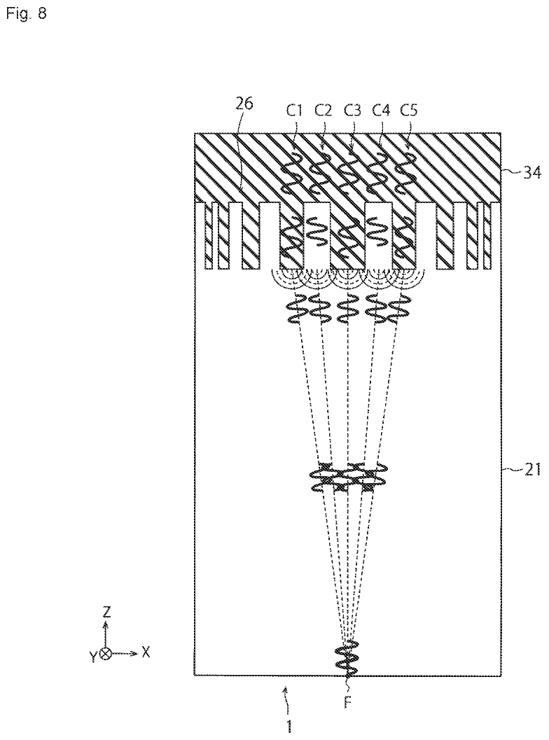

In FIG. 7, A shows a vertical cross section of the solid-state imaging device of the comparative example, and in FIG. 7, B shows a vertical cross section of the solid-state imaging device of the present embodiment. For the sake of clarity, the components of the comparative example are shown using the same reference numerals as used for denoting the components of the present embodiment. Further, in A and B of FIG. 7, components not directly related to the explanation such as the photoelectric conversion unit 22, the element separation portion 32, and the fixed charge film 33 are omitted (the same applies to FIG. 8 and the like described hereinbelow).

As shown in A of FIG. 7, the solid-state imaging device of the comparative example includes a moth-eye structure 26′ instead of the zone plate 26. Similar to the zone plate 26, the moth-eye structure 26′ is formed by forming a plurality of recesses on the back surface of the substrate 21 and embedding a fixed charge film 33 and an insulating film 34 in these recesses. With the moss eye structure 26′, the reflection of the incident light can be reduced and the sensitivity of the solid-state imaging device can be improved.

However, the recesses of the moth-eye structure 26′ are formed in a two-dimensional array in which a plurality of recesses are present in a grid pattern along the X and Y directions, rather than in the annular shape. Therefore, the moth-eye structure 26′ may scatter the incident light A1 falling on each pixel 1 on the adjacent pixels 1 (see scattered light A2) to cause color mixing between the pixels 1.

By contrast, as shown in B of FIG. 7, the solid-state imaging device of the present embodiment includes the zone plate 26. Since the zone plate 26 has an uneven shape similar to the moth-eye structure 26′, it is possible to reduce the reflection of incident light and improve the sensitivity of the solid-state imaging device. In addition, the uneven shape of the zone plate 26 is formed by the first annular portions 51, the second annular portions 52, and the like, and the zone plate 26 generally demonstrates a light condensing action like a lens. Therefore, since the zone plate 26 can condense the incident light B1 falling on each pixel 1 (see condensed light B2), it is possible to reduce color mixing between the pixels 1.

The zone plate 26 may have a shape such that the incident light is less scattered to the adjacent pixels 1. The reason is that if the scattering of the incident light is small, color mixing between the pixels 1 can be reduced. For example, the first and second annular portions 51 and 52 have central axes at the same position in the present embodiment, but may have central axes at different positions. Further, in the present embodiment, the width of the first annular portions 51 and the width of the second annular portions 52 satisfy the condition that the width becomes smaller as the distance from the center of these annular portions increases, but this condition may not be satisfied. Further, the zone plate 26 may be replaced with another optical element capable of condensing incident light and/or capable of suppressing scattering of incident light.

FIG. 8 is a cross-sectional view for explaining the operation of the zone plate 26 of the first embodiment.

FIG. 8 schematically shows an incident light C1 on the second annular portion 52, an incident light C2 on the first annular portion 51, an incident light C3 on the non-annular portion 53, an incident light C4 on the first annular portion 51, and an incident light C5 on the second annular portion 52. At least a part of each incident light C1 to C5 passes through the first annular portions 51, the second annular portions 52, and the non-annular portion 53.

The first annular portions 51 in FIG. 8 have a refractive index different from that of the second annular portions 52 and the non-annular portion 53. Therefore, a phase difference occurs between the incident lights C2 and C4 in the first annular portions 51 and the incident lights C1, C3 and C5 in the second annular portions 52 and the non-annular portion 53. Where these incident lights C1 to C5 pass thereafter through the zone plate 26 and are diffracted, the phases of these incident lights C1 to C5 are aligned at a predetermined point F (focus) in the photoelectric conversion unit 22. In this way, the incident lights C1 to C5 are condensed on the point F. The point F is located on the above-mentioned central axis L.

The zone plate 26 shown in FIG. 8 is a phase-type zone plate. The substrate 21 included in the first annular portions 51 is, for example, a silicon substrate. The fixed charge film 33 and the insulating film 34 included in the second annular portions 52 and the non-annular portion 53 are, for example, a tantalum oxide film and a silicon oxide film, respectively. As a result, the first annular portions 51 have a refractive index different from that of the second annular portions 52 and the non-annular portion 53. The refractive index of the second annular portions 52 and the non-annular portion 53 is the average refractive index of the fixed charge film 33 and the insulating film 34, but when the fixed charge film 33 is significantly thinner than the insulating film 34, the refractive index of the second annular portions 52 and the non-annular portion 53 roughly matches the refractive index of the insulating film 34.

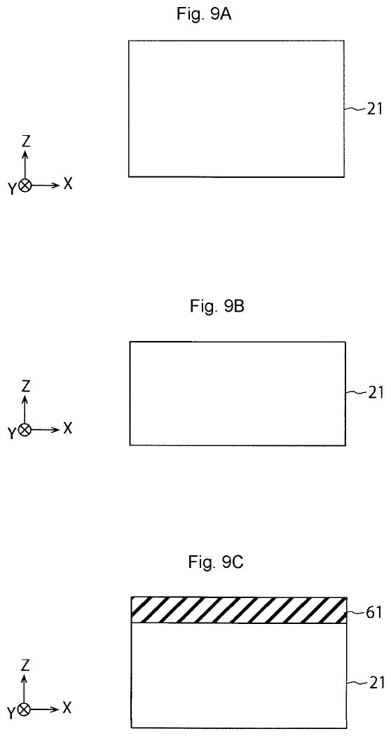

FIGS. 9 to 11 are sectional views showing a method for forming the zone plate 26 of the first embodiment.

In FIG. 9, A shows a substrate 21 in a state where the front side of the substrate 21 is facing downward and the back side of the substrate 21 is facing upward. Therefore, the upper surface of the substrate 21 in A of FIG. 9 is the back surface of the substrate 21.

First, as shown in B of FIG. 9, the back surface of the substrate 21 is polished by CMP (Chemical Mechanical Polishing). As a result, the substrate 21 is thinned from the back surface as described above.

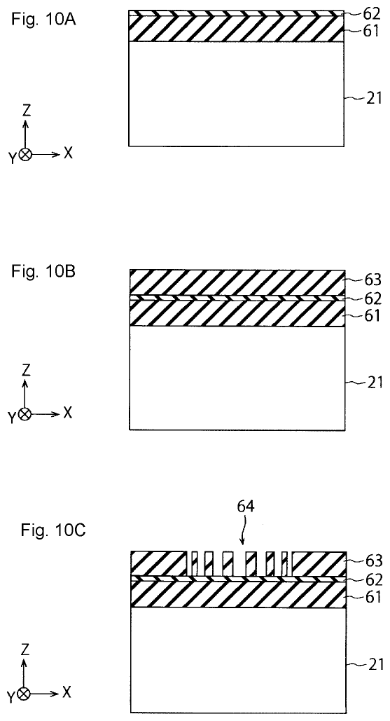

Next, as shown in C of FIG. 9, A of FIG. 10, and B of FIG. 10, a hard mask layer 61, a BARC (Bottom Anti-Reflective Coating) layer 62, and a resist layer 63 are formed in this order on the back surface of the substrate 21. The hard mask layer 61 is, for example, a silicon oxide film. The BARC layer 62 is, for example, an organic film. The BARC layer 62 and the resist layer 63 are formed by, for example, a coating method.

Next, as shown in C of FIG. 10, a resist pattern 64 composed of a plurality of recesses is formed in the resist layer 63 by photolithography. These recesses have a planar shape corresponding to the second annular portions 52 and the non-annular portion 53.

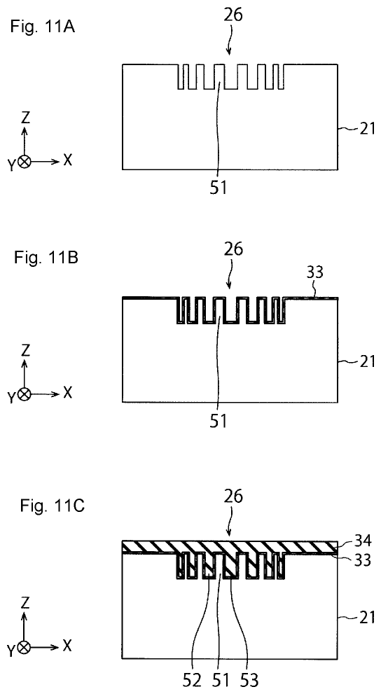

Next, as shown in A of FIG. 11, the resist pattern 64 is transferred to the substrate 21 (p-type semiconductor region 25) by etching. As a result, the first annular portions 51 for the zone plate 26 are formed between the recesses transferred to the substrate 21.

Next, as shown in B of FIG. 11, the fixed charge film 33 is formed on the back surface of the substrate 21. As a result, the fixed charge film 33 is formed on the side surface and the bottom surface of the recesses between the first annular portions 51.

Next, as shown in C of FIG. 11, the insulating film 34 is formed on the back surface of the substrate 21. As a result, the insulating film 34 is embedded in the recesses between the first annular portions 51 with the fixed charge film 33 interposed therebetween. As a result, second annular portions 52 and the non-annular portion 53 for the zone plate 26 are formed in these recesses.

In this way, the zone plate 26 shown in FIG. 6 is formed.

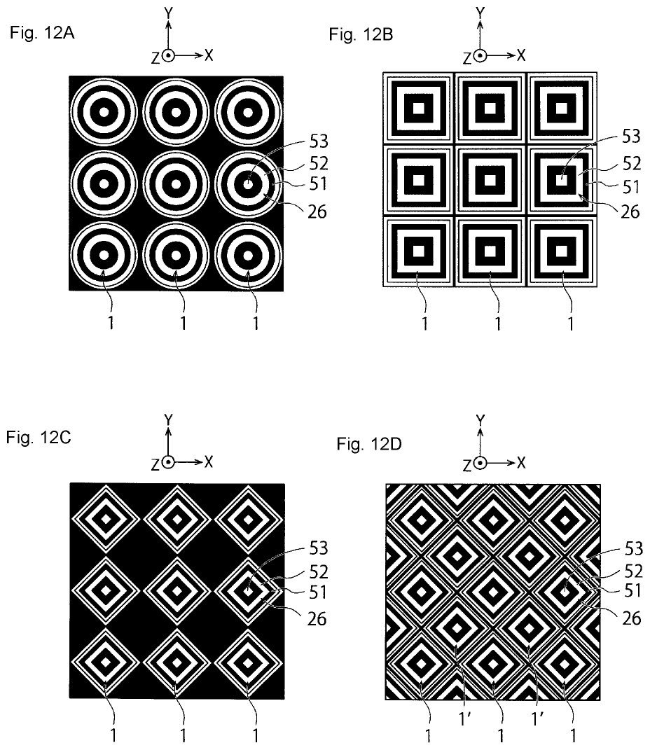

Hereinafter, various examples of the zone plate 26 of the present embodiment will be described with reference to FIGS. 12 to 15.

FIG. 12 is a plan view showing examples of the zone plate 26 of the first embodiment.

In A of FIG. 12, the upper and lower first and second annular portions 51 and 52 of each zone plate 26 have circular annular shapes. The shape of the non-annular portion 53 is circular. Such a zone plate 26 has an advantage that, for example, the light condensing performance is high. In A of FIG. 12, nine zone plates 26 provided for the nine pixels 1 are shown.

In B of FIG. 12, the upper and lower first and second annular portions 51 and 52 of each zone plate 26 have quadrangular (square) ring shape. The shape of the non-annular portion 53 is a quadrangle. For example, such a zone plate 26 has an advantage that the zone plate 26 can be easily formed. In FIG. 12, B shows nine zone plates 26 provided for the nine pixels 1.

In C of FIG. 12, the upper and lower first and second annular portions 51 and 52 of each zone plate 26 have a quadrangular ring shape, as in B of FIG. 12. However, while each side of the quadrangle B in FIG. 12 is parallel to the X or Y direction, each side of the quadrangle C in FIG. 12 is non-parallel to the X and Y directions. In FIG. 12, C shows nine zone plates 26 provided for the nine pixels 1.

In D of FIG. 12, the upper and lower first and second annular portions 51 and 52 of each zone plate 26 have a quadrangular ring shape as in C of FIG. 12. However, in D of FIG. 12, not only the zone plate 26 is provided at the position of each pixel 1, but also the zone plates 26 are provided at the positions between the pixels 1 as indicated by reference numeral 1′. As described above, the solid-state imaging device of the present embodiment may include more zone plates 26 than the pixels 1.

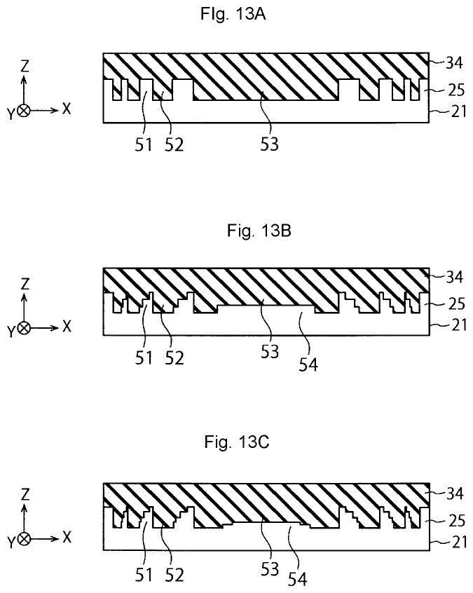

FIG. 13 is a cross-sectional view showing other examples of the zone plate 26 of the first embodiment.

The zone plate 26 shown in A of FIG. 13 is a two-level phase-type zone plate similar to the zone plate 26 shown in FIG. 8. Therefore, the first annular portions 51 in this case have a refractive index different from that of the second annular portions 52 and the non-annular portion 53.

The zone plate 26 shown in B of FIG. 13 is a four-level phase-type zone plate, and the first annular portions 51 in this case have three kinds of thicknesses. In this case, the non-annular portion 54 including the p-type semiconductor region 25 in the substrate 21 is provided under the non-annular portion 53 including the fixed charge film 33 and the insulating film 34. The first annular portions 51 and the non-annular portion 54 in this case have a refractive index different from that of the second annular portions 52 and the non-annular portion 53.

The zone plate 26 shown in C of FIG. 13 is an N-level (N is an integer of 2 or more) phase-type zone plate, and the first annular portions 51 in this case have N−1 kinds of thicknesses. In this case, the non-annular portion 54 including the p-type semiconductor region 25 in the substrate 21 is provided under the non-annular portion 53 including the fixed charge film 33 and the insulating film 34. The first annular portions 51 and the non-annular portion 54 in this case have a refractive index different from that of the second annular portions 52 and the non-annular portion 53. More specifically, the zone plate 26 shown in C of FIG. 13 has a shape that is called Blaze Kinoform and is similar to a Fresnel lens.

The zone plate 26 of the present embodiment may have any of the shapes A to C in FIG. 13. The zone plate 26 shown in A of FIG. 13 has an advantage that, for example, it is easy to manufacture. Meanwhile, the zone plates 26 shown in B and C of FIG. 13 have an advantage that, for example, good light condensing performance can be easily realized.

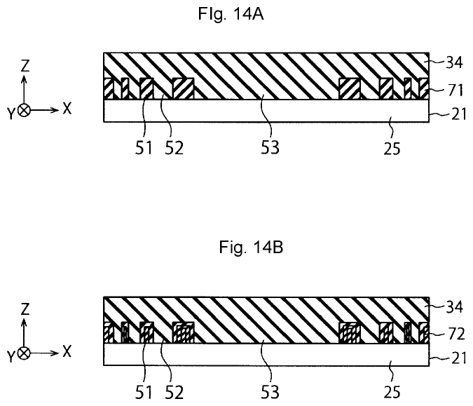

FIG. 14 is a cross-sectional view showing other examples of the zone plate 26 of the first embodiment.

The zone plate 26 shown in A of FIG. 14 is an amplitude-type zone plate. Therefore, the first annular portions 51 in this case have a transmittance different from the transmittance of the second annular portions 52 and the non-annular portion 53. The first annular portion 51 includes an insulating film 71 provided on the back surface of the substrate 21, rather than the substrate 21. The insulating film 71 is, for example, an organic film. Meanwhile, the fixed charge film 33 and the insulating film 34 are, for example, a tantalum oxide film and a silicon oxide film, respectively. The transmittance of the second annular portions 52 and the non-annular portion 53 is the average transmittance of the fixed charge film 33 and the insulating film 34, but when the fixed charge film 33 is significantly thinner than the insulating film 34, the transmittance of the second annular portion 52 and the non-annular portion 53 roughly matches the transmittance of the insulating film 34. The zone plate 26 shown in A of FIG. 14 is called a Fresnel zone plate.

The zone plate 26 shown in B of FIG. 14 is also an amplitude-type zone plate. Therefore, the first annular portions 51 in this case have a transmittance different from the transmittance of the second annular portions 52 and the non-annular portion 53. The first annular portion 51 includes an insulating film 72 provided on the back surface of the substrate 21, rather than the substrate 21. The insulating film 72 is, for example, an organic film. Meanwhile, the fixed charge film 33 and the insulating film 34 are, for example, a tantalum oxide film and a silicon oxide film, respectively. Further, each first annular portion 51 in this case has a structure in which the transmittance gradually changes from the vicinity of the center thereof to the vicinity of the outer surface thereof. Such a first annular portion 51 can be realized, for example, by gradually changing the concentration of an organic substance in the organic film (insulating film 72) from the vicinity of the center of each first annular portion 51 to the vicinity of the outer surface. The zone plate 26 shown in B of FIG. 14 is called a Gabor zone plate.

The zone plate 26 of the present embodiment may have either of the shapes shown in A and B of FIG. 14. The zone plate 26 shown in A of FIG. 14 has an advantage that, for example, it is easy to manufacture. Meanwhile, the zone plate 26 shown in B of FIG. 14 has an advantage that, for example, good light condensing performance can be easily realized.

Further, the first annular portions 51 for the zone plate 26 of the present embodiment may be formed by using the substrate 21 as shown in A to C of FIG. 13, or may be formed by using another film on the substrate 21 as shown in in A to C of FIG. 14. In the former case, there is an advantage that, for example, the cost and labor for forming another film on the substrate 21 can be reduced. Meanwhile, in the latter case, there is an advantage that, for example, the first annular portions 51 having desired characteristics can be easily realized.

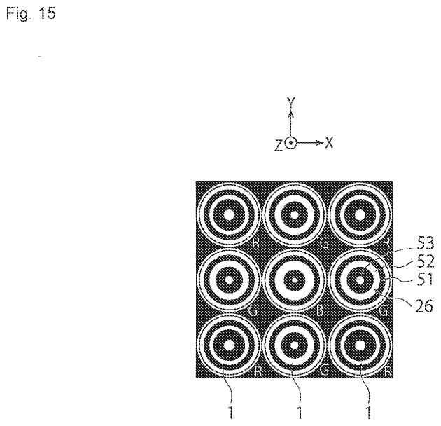

FIG. 15 is a plan view showing another example of the zone plate 26 of the first embodiment.

FIG. 15 shows the zone plate 26 for the red pixel 1, the zone plate 26 for the green pixel 1, and the zone plate 26 for the blue pixel 1. In FIG. 15, the shape of the zone plate 26 is different for each type of color of pixel 1 (that is, for each type of color transmitted through the corresponding color filter layer 37). Specifically, the width of each first annular portion 51, the width of each second annular portion 52, and the width of the non-annular portion 53 differ between the zone plate 26 for red, the zone plate 26 for green, and the zone plate 26 for blue. This makes it possible for the zone plates 26 to exhibit different performance depending on, for example, the color (wavelength) of the incident light.

The difference in the shape of the zone plate 26 for each color may be realized by a method other than changing the width of the annular portions or the non-annular portion. For example, the shape of each annular portion of the zone plate 26 of one color may be set to a circular annular shape, and the shape of each annular portion of the zone plate 26 of another color may be set to a quadrangular annular shape.

As described above, the solid-state imaging device of the present embodiment includes the zone plate 26 provided between the photoelectric conversion unit 22 and the on-chip lens 38. Therefore, according to the present embodiment, it is possible to reduce color mixing between the pixels 1 by condensing the incident light from the on-chip lens 38 by the zone plate 26. Further, according to the present embodiment, even if color mixing cannot be sufficiently reduced only by the element separation portion 32 and the light-shielding film 35, the zone plate 26 can effectively reduce color mixing.

### Second Embodiment

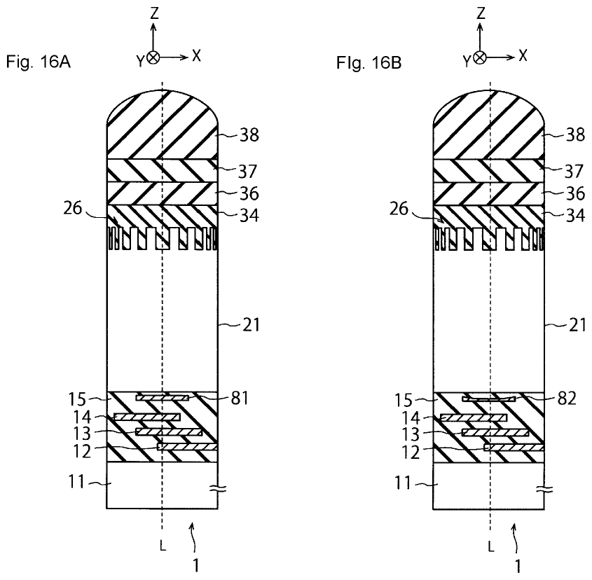

FIG. 16 is a cross-sectional view showing the structure of the solid-state imaging device of the second embodiment and the solid-state imaging device of a modification example thereof. In A and B of FIG. 16, the components not directly related to the explanation such as the photoelectric conversion unit 22, the element separation portion 32, and the fixed charge film 33 and the components sufficiently shown in other figures are omitted.

In FIG. 16, A shows a vertical cross section of the solid-state imaging device of the present embodiment, and more specifically, shows a vertical cross section of the pixel region 2 in FIG. 1. The configuration shown in FIG. 1 is common to the first embodiment and the present embodiment. In addition to the components shown in FIG. 2, the solid-state imaging device of the present embodiment includes a reflector 81 provided for each pixel 1.

The reflector 81 is provided in the interlayer insulating film 15, and specifically, between the substrate 21 (photoelectric conversion unit 22) and the wiring layers 12 to 14. The reflector 81 is a layer formed of a material that reflects light, for example, a layer including an element such as tungsten, aluminum, or copper. According to the present embodiment, it is possible to prevent the light condensed by the zone plate 26 from being incident on the wiring layers 12 to 14 from the photoelectric conversion unit 22, and the sensitivity of the solid-state imaging device can be improved by reflecting this light to the photoelectric conversion unit 22.

The zone plate 26 of the present embodiment condenses light at a point on the central axis L. Therefore, it is desirable that the reflector 81 be arranged at a position overlapping the central axis L. As a result, the reflector 81 can be arranged at a position where the light intensity is strong, and the light that has passed through the substrate 21 can be effectively reflected by the reflector 81.

The reflector 81 may have a large area that occupies most of the area of each pixel 1, or conversely, may have only a narrow area. It is considered that the larger the area of the reflector 81, the more effectively the light can be reflected by the reflector 81. However, in the present embodiment, since the zone plate 26 condenses the light on the photoelectric conversion unit 22, the light can be sufficiently reflected by the reflector 81 even if the area of the reflector 81 is small. In other words, according to the present embodiment, the reflector 81 can be miniaturized by condensing the light by the zone plate 26.

The reflector 81 may be formed, for example, by using the same material as that of the wiring layers 12 to 14. In this case, the reflector 81 can be formed by the same method as the wiring layers 12 to 14. The reflector 81 may be provided in the wiring layer including the wiring and the reflector 81. Meanwhile, when the gate electrodes 16, 41, 42, and 43 are formed by using a metal material, the reflector 81 may be provided in the metal layer including the gate electrodes 16, 41, 42, and 43 and the reflector 81.

In FIG. 16, B shows a vertical cross section of the solid-state imaging device of the modification example of the present embodiment, and more specifically, shows a vertical cross section of the pixel region 2 of FIG. 1. The solid-state imaging device of this modification example has a structure in which the reflector 81 of the solid-state imaging device in A of FIG. 16 is replaced with a reflector 82.

The upper surface of the reflector 82 (the surface on the substrate 21 side) has a concave shape. Therefore, the reflector 82 of each pixel 1 can reflect the light that has passed through the substrate 21 so as to condense the light on the corresponding photoelectric conversion unit 22. As a result, it is possible to prevent the reflected light from the reflector 82 from being scattered to the adjacent pixel 1. Other properties of the reflector 82 are the same as those of the reflector 81 described above.

As described above, according to the present embodiment, it is possible to improve the sensitivity of the solid-state imaging device by reflecting the light that has passed through the substrate 21 by the reflector 81 or the reflector 82.

### Third Embodiment

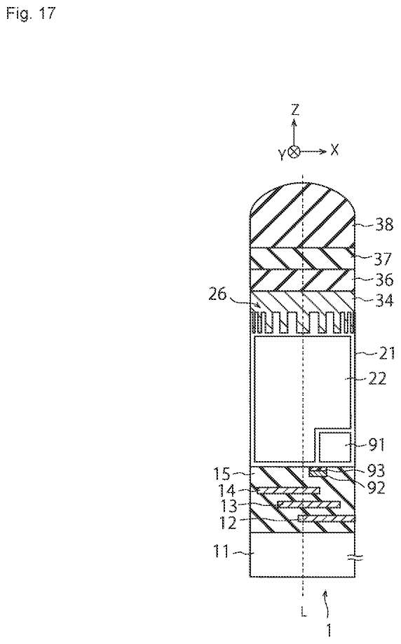

FIG. 17 is a cross-sectional view showing the structure of the solid-state imaging device of the third embodiment. In FIG. 17, the components not directly related to the explanation such as the element separation portion 32 and the fixed charge film 33 and the components sufficiently shown in other figures are omitted.

FIG. 17 shows a vertical cross section of the solid-state imaging device of the present embodiment, and more specifically, shows a vertical cross section of the pixel region 2 of FIG. 1. The configuration shown in FIG. 1 is common to the first embodiment and the present embodiment. In addition to the components shown in FIG. 2, the solid-state imaging device of the present embodiment includes a memory unit 91, and a gate electrode 92 and a gate insulating film 93 of a MOS transistor for the memory unit 91.

The memory unit 91 is provided below the photoelectric conversion unit 22 in the substrate 21, and is provided on the front side of the substrate 21 with respect to the photoelectric conversion unit 22. In other words, the memory unit 91 is provided in the substrate 21 between the photoelectric conversion unit 22 and the surface of the substrate 21 in the −Z direction. As described above, the photoelectric conversion unit 22 includes the p-type semiconductor region 23, the n-type semiconductor region 24, and the p-type semiconductor region 25, which are sequentially formed in the substrate 21 from the front side to the back side of the substrate 21. Similarly, the memory unit 91 of the present embodiment also has a p-type semiconductor region, an n-type semiconductor region, and a p-type semiconductor region (not shown) sequentially formed in the substrate 21 from the front side to the back side of the substrate 21. The memory unit 91 functions as a charge holding unit that holds the signal charge generated by the photoelectric conversion unit 22. The memory unit 91 of the present embodiment is provided at a position that does not overlap with the central axis L.

The gate electrode 92 of the MOS transistor for the memory unit 91 is provided under the region (p-well layer 28) between the photoelectric conversion unit 22 and the memory unit 91, with the gate insulating film 93 interposed therebetween. This MOS transistor can transfer the signal charge in the photoelectric conversion unit 22 to the memory unit 91. The gate electrode 92 and the gate insulating film 93 are provided in the interlayer insulating film 15 in the same manner as the gate electrode 16 and the gate insulating film 17 of the transfer transistor Tr1.

Since the memory unit 91 is provided to hold the signal charge generated by the photoelectric conversion unit 22, it is preferable that light be not incident on the memory unit 91. When light is incident on the memory unit 91, a problem called PLS (Parasitic Light Sensitivity) may occur in the memory unit 91. Therefore, it is conceivable to form some kind of film around the memory unit 91, but in that case, a step of forming the film is required.

However, the solid-state imaging device of the present embodiment includes the zone plate 26 that condenses the light from the on-chip lens 38 on the photoelectric conversion unit 22. Therefore, where the memory unit 91 is arranged away from the point where the light is condensed by the zone plate 26, it is possible to prevent the light from being incident on the memory unit 91. For this reason, the memory unit 91 of the present embodiment is provided at a position that does not overlap with the central axis L including the point where the light from the zone plate 26 is condensed. As a result, even if the memory unit 91 is provided below the photoelectric conversion unit 22, it is possible to prevent the incident light from being incident on the memory unit 91, and it is possible to reduce the occurrence of PLS in the memory unit 91.

As described above, according to the present embodiment, by providing the zone plate 26 between the on-chip lens 38 and the photoelectric conversion unit 22, it is possible to prevent the incident light from being incident on the memory unit 91 even if the memory unit 91 is provided below the photoelectric conversion unit 22.

Further, according to the present embodiment, by providing the memory unit 91 at a position that does not overlap with the central axis L, it is possible to prevent the incident light from being incident on the memory unit 91 even if the incident light from the zone plate 26 is condensed in a point on the central axis L.

### Fourth Embodiment

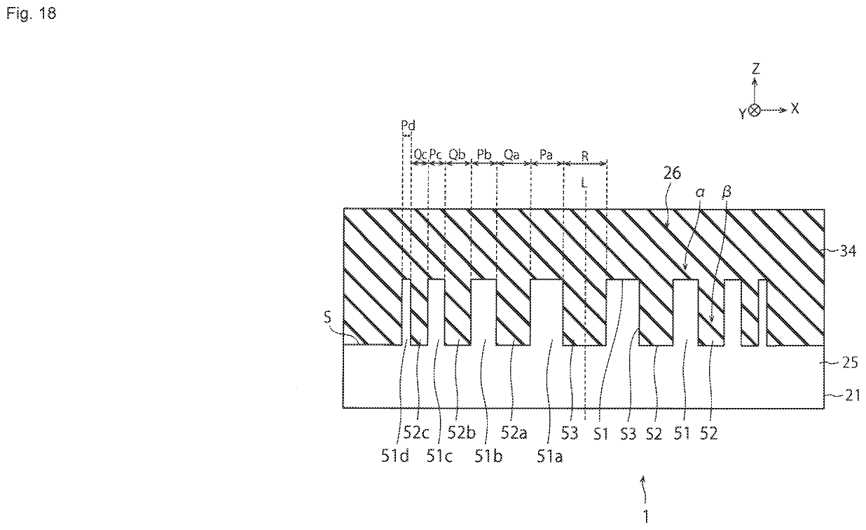

FIG. 18 is a cross-sectional view showing the shape of the zone plate 26 of the fourth embodiment. The zone plate 26 of the present embodiment corresponds to a modification example of the zone plate 26 shown in FIG. 6 in the first embodiment. The configurations shown in FIGS. 1 and 2 are common to the first embodiment and the present embodiment. In FIG. 18, the fixed charge film 33 is not shown in order to make the drawings easier to see. The shape and arrangement of the fixed charge film 33 are shown in FIG. 2 and the like.

Similar to the zone plate 26 shown in FIG. 6, the zone plate 26 of the present embodiment includes a plurality of first annular portions 51 including the p-type semiconductor region 25, and a plurality of second annular portions 52 and the non-annular portions 53 including the fixed charge film 33 and the insulating film 34.

However, in the zone plate 26 of the present embodiment, unlike the zone plate 26 shown in FIG. 6, the first annular portions 51, the second annular portions 52, and the non-annular portion 53 are provided at positions higher than the back surface S of the substrate 21 around the zone plate 26. Such a structure can be realized by etching the entire region around the region forming the first annular portion 51 of the back surface S of the substrate 21 when forming the first annular portions 51 by etching on the back surface S of the substrate 21.

However, at this time, it is not necessary to etch the region where the groove 31 has been formed or the like.

FIG. 18 shows the uneven shape of the zone plate 26, and the uneven shape shows the cross sections of the first annular portions 51, the second annular portions 52, and the non-annular portion 53. The uneven shape of the zone plate 26 in FIG. 18 includes a plurality of protrusions a protruding in the Z direction with respect to the back surface S of the substrate 21, and a plurality of recesses ß recessed in the −Z direction with respect to the top surface 51 of the protrusions α. In other words, the protrusions α project in the Z direction with respect to the bottom surface S2 of the recesses ß. The zone plate 26 has an uneven shape including the top surfaces 51 of the protrusions α, the bottom surfaces S2 of the recesses ß, and the side surface S3 between the top surface 51 and the bottom surface S2.

The structure shown in FIG. 18 may be applied to the zone plate 26 (amplitude-type zone plate) shown in A and B of FIG. 14. However, in this case, the first annular portions 51 are formed by using the insulating film 71 (or the insulating film 72) provided on the back surface S of the substrate 21.

FIG. 18 illustrates four first annular portions 51a to 51d as the first annular portions 51, and three second annular portions 52a to 52c as the second annular portions 52. Since the positions of the back surface S in FIG. 6 and FIG. 18 are different, the numbers of the second annular portions 52 in FIG. 6 and FIG. 18 are different. FIG. 18 further shows the widths Pa to Pd of the first annular portions 51a to 51d, the widths Qa to Qc of the second annular portions 52a to 52c, and the width R of the non-annular portion 53. The shapes and materials of the first annular portion 51, the second annular portion 52, and the non-annular portion 53 of the present embodiment are the same as those of the zone plate 26 shown in FIG. 6.

As described above, according to the present embodiment, it is possible to provide the zone plate 26 in which the position of the back surface S is different from that of the zone plate 26 of the first embodiment. The zone plate 26 of the first embodiment has an advantage that, for example, when the first annular portions 51 are formed by using the p-type semiconductor region 25, the etching amount of the p-type semiconductor region 25 can be small. Meanwhile, the zone plate 26 of the present embodiment has an advantage that, for example, when the first annular portions 51 are formed by using the insulating film 71, the unnecessary insulating film 71 does not remain on the substrate 21.

### Modification Example

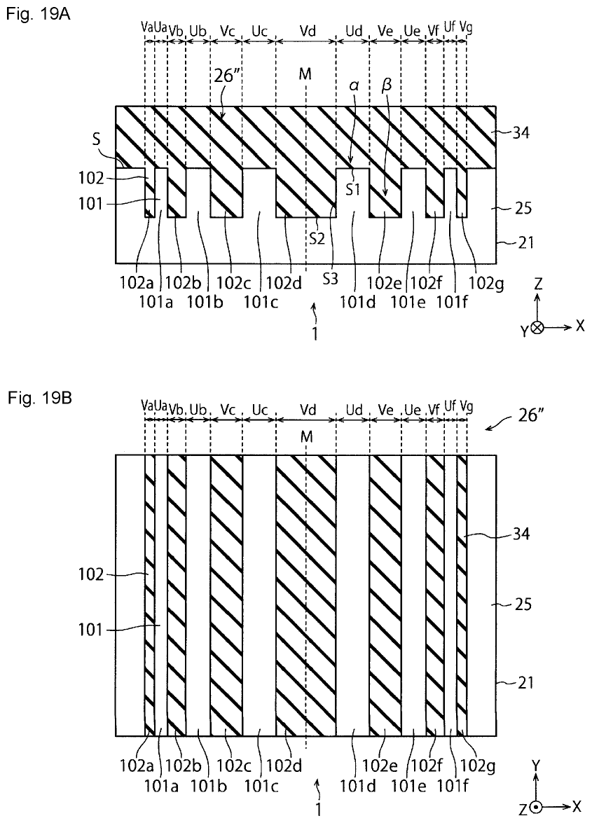

In the first to fourth embodiments, the zone plate 26 has been described as an example of the light condensing unit between the on-chip lens 38 and the photoelectric conversion unit 22, but as shown in FIG. 19, another light condensing unit 26″ may be provided between the on-chip lens 38 and the photoelectric conversion unit 22.

FIG. 19 is a cross-sectional view showing the shape of the light condensing unit 26″ of the modification example of the first to fourth embodiments. In FIG. 19, A shows an XZ cross section of the light condensing unit 26″. In FIG. 19, B shows an XY cross section of the light condensing unit 26″. The light condensing unit 26″ is realized by a plurality of first straight portions 101 that extend linearly in the Y direction and include the p-type semiconductor region 25, and a plurality of second straight portions 102 that extend linearly in the Y direction and include the fixed charge film 33 and the insulating film 34. These first straight portions 101 and second straight portions 102 are provided alternately. In A and B of FIG. 19, the fixed charge film 33 is omitted in order to make the drawings easier to see.

In FIG. 19, A and B exemplify six first straight portions 101a to 101f as the first straight portions 101, and exemplify seven second straight portions 102a to 102g as the second straight portions 102. The first straight portions 101a to 101f are arranged so that the distance thereof from the center of these straight portions increases in the order of 101c, 101b, 101a and the order of 101d, 101e, 101f. Similarly, the second straight portions 102a to 102g are arranged so that the distance thereof from the center of these straight portions increases in the order of 102d, 102c, 102b, 102a and the order of 102d, 102e, 102f, 102g.

A and B in FIG. 19 further show widths Ua to Uf of the first straight portions 101a to 101g and widths Va to Vg of the second straight portions 102a to 102d. In the present modification example, the widths Ua to Uf of the first straight portions 101a to 101f are set so as to become smaller as the distance from the center portion of these straight portions increases. Further, the widths Va to Vg of the second straight portions 102a to 102g are set so as to become smaller as the distance from the center of these straight portions increases. The first straight portions 101a to 101f and the second straight portions 102a to 102g of the present modification example have a shape symmetrical with respect to the plane M. Therefore, in the present modification example, the widths Ua, Ub, and Uc are equal to the widths Uf, Ue, and Ud, respectively, and the widths Va, Vb, and Vc are equal to the widths Vg, Vf, and Ve, respectively.

The uneven shape of the light condensing unit 26″ in A of FIG. 19 includes a plurality of recesses ß recessed in the −Z direction with respect to the back surface S of the substrate 21, and a plurality of protrusions a protruding in the Z direction with respect to the bottom surface S2 of these recesses ß. In other words, the recesses ß are recessed in the −Z direction with respect to the top surface S1 of the protrusions α.

This light condensing unit 26″, unlike the zone plate 26 of each embodiment, condenses light only in the X direction and does not condense light in the Y direction. However, such a light condensing unit 26″ can also reduce color mixing between the pixels 1.

As described above, according to the present modification example, it is possible to reduce color mixing between the pixels 1 by the light condensing unit 26″ which is different from the zone plate 26. The light condensing unit 26″ of the present modification example has an advantage that, for example, the structure is generally simpler and easier to manufacture than in the case of the zone plate 26. Meanwhile, the zone plates 26 of the first to fourth embodiments have an advantage that, for example, light can be easily condensed near the center of each pixel 1, and color mixing between the pixels 1 can be effectively reduced.

Although the embodiments of the present disclosure have been described above, these embodiments may be implemented with various modifications without departing from the gist of the present disclosure. For example, two or more embodiments may be combined and implemented.

The present disclosure may also have the following configurations.

(1) A solid-state imaging device including a substrate and a photoelectric conversion unit provided in the substrate, wherein a plurality of protrusions are provided on a light incident surface of the substrate, and the width of the protrusion becomes smaller as the distance from the center of the plurality of protrusions increases.

(2) The solid-state imaging device according to (1), wherein each of the plurality of protrusions has an annular shape in a plan view.

(3) The solid-state imaging device according to (2), wherein the plurality of protrusions have a concentric annular shape in a plan view.

(4) The solid-state imaging device according to (2), wherein each of the plurality of protrusions has a circular or quadrangular annular shape in a plan view.

(5) The solid-state imaging device according to (1), wherein a plurality of recesses are provided alternately with the plurality of protrusions on the light incident surface of the substrate, and the width of the recess becomes smaller as the distance from the center of the plurality of recesses increases.

(6) The solid-state imaging device according to (5), wherein each of the plurality of recesses has an annular shape in a plan view.

(7) The solid-state imaging device according to (6), wherein the plurality of recesses have a concentric annular shape in a plan view.

(8) The solid-state imaging device according to (6), wherein each of the plurality of recesses has a circular or quadrangular annular shape in a plan view.

(9) The solid-state imaging device according to (6), further including recesses that are provided inside the plurality of protrusions, have a non-annular shape in a plan view, and are recessed on the photoelectric conversion unit side with respect to the top surface of the protrusion.

(10) The solid-state imaging device according to (9), wherein the recess having the non-annular shape has a circular or quadrangular shape in a plan view.

(11) The solid-state imaging device according to (1), further including a first material provided in the protrusions, and a second material that is provided between the protrusions and is different from the first material.

(12) The solid-state imaging device according to (11), wherein the first material serves as a material for a semiconductor region in the photoelectric conversion unit and also as a material for the protrusions.

(13) The solid-state imaging device according to (11), wherein the second material includes a film having a negative fixed charge.

(14) The solid-state imaging device according to (13), wherein the second material includes a first film having a negative fixed charge and a second film different from the first film.

(15) The solid-state imaging device according to (11), further including an element separation portion provided between the photoelectric conversion units adjacent to each other, wherein the second material includes an insulating material which is a material of the element separation portion.

(16) The solid-state imaging device according to (11), wherein the first material and the second material have different light transmittances or refractive indexes from each other.

(17) The solid-state imaging device according to (1), further including a lens that condenses light and causes the light to fall on the protrusions, and a color filter layer provided between the lens and the protrusions, wherein the shape of the protrusions differs for each type of color transmitted through the color filter layer.

(18) The solid-state imaging device according to (1), further including a wiring layer provided on a surface of the substrate opposite to the light incident surface, and a reflector that is provided between the photoelectric conversion unit and the wiring layer and reflects light from the photoelectric conversion unit.

(19) The solid-state imaging device according to (18), wherein the surface of the reflector on the photoelectric conversion portion side has a recessed shape.

(20) The solid-state imaging device according to (18), wherein the plurality of protrusions have a concentric annular shape having a central axis at the same position in a plan view, and the reflector is provided at a position overlapping the central axis.

(21) The solid-state imaging device according to (1), further including a memory unit that is provided between the photoelectric conversion unit and a surface of the substrate opposite to the light incident surface and that holds a charge from the photoelectric conversion unit.

(22) The solid-state imaging device according to (21), wherein the plurality of protrusions have a concentric annular shape having a central axis at the same position in a plan view, and the memory unit is provided at a position not overlapping the central axis.

(23) A solid-state imaging device including a lens that condenses light, a photoelectric conversion unit that converts light from the lens into a charge, and a light condensing unit that is provided between the lens and the photoelectric conversion unit and condenses light from the lens on the photoelectric conversion unit.

(24) The solid-state imaging device according to (23), wherein the photoelectric conversion unit is provided in a substrate, and the light condensing unit condenses light from the lens on the photoelectric conversion unit by a plurality of protrusions provided on a light incident surface of the substrate.

(25) The solid-state imaging device according to (23), including a plurality of the lenses, a plurality of the photoelectric conversion units, and a plurality of the light condensing units, wherein each of the light condensing units is provided between one corresponding lens and one corresponding photoelectric conversion unit.

(26) A method for manufacturing a solid-state imaging device, including: forming a photoelectric conversion unit in the substrate, and forming a plurality of protrusions on a light incident surface of the substrate so that the width of the protrusion becomes smaller as the distance from the center of the plurality of protrusions increases.

(27) The method for manufacturing a solid-state imaging device according to (26), wherein the protrusions are formed in a semiconductor region by processing the semiconductor region in the photoelectric conversion unit.

(28) The method for manufacturing a solid-state imaging device according to (26), further including embedding a second material different from the first material located in the protrusion between the protrusions.

### REFERENCE SIGNS LIST

1 Pixel
2 Pixel region
3 Control circuit
4 Vertical drive circuit
5 Column signal processing circuit
6 Horizontal drive circuit
7 Output circuit
8 Vertical signal line
9 Horizontal signal line
11 Support substrate
12, 13, 14 Wiring layer
15 Interlayer insulating film
16 Gate electrode
17 Gate insulating film
21 Substrate
22 Photoelectric conversion unit
23 p-Type semiconductor region
24 n-Type semiconductor region
25 p-Type semiconductor region
26 Zone plate
26′ Moth-eye structure
26″ Light condensing unit
27 Pixel separation layer
28 p-Well layer
29 Floating diffusion portion
31 Groove
32 Element separation portion
33 Fixed charge film
34 Insulating film
35 Light-shielding film
36 Flattening film
37 Color filter layer
38 On-chip lens
41, 42, 43 Gate electrode
44, 45, 46, 47 Source-drain region
51 First annular portion
52 Second annular portion
53, 54 Non-annular portion
61 Hard mask layer
62 BARC layer
63 Resist layer
64 Resist pattern
71, 72 Insulating film
81, 82 Reflector
91 Memory unit
92 Gate electrode
93 Gate insulating film
101 First straight portion
102 Second straight portion

1. A solid-state imaging device comprising a substrate and a photoelectric conversion unit provided in the substrate, wherein a plurality of protrusions are provided on a light incident surface of the substrate, and the width of the protrusion becomes smaller as the distance from the center of the plurality of protrusions increases.

2. The solid-state imaging device according to claim 1, wherein each of the plurality of protrusions has an annular shape in a plan view.

3. The solid-state imaging device according to claim 2, wherein the plurality of protrusions have a concentric annular shape in a plan view.

4. The solid-state imaging device according to claim 2, wherein each of the plurality of protrusions has a circular or quadrangular annular shape in a plan view.

5. The solid-state imaging device according to claim 1, wherein a plurality of recesses are provided alternately with the plurality of protrusions on the light incident surface of the substrate, and the width of the recess becomes smaller as the distance from the center of the plurality of recesses increases.

6. The solid-state imaging device according to claim 5, wherein each of the plurality of recesses has an annular shape in a plan view.

7. The solid-state imaging device according to claim 1, further comprising a first material provided in the protrusions, and a second material that is provided between the protrusions and is different from the first material.

8. The solid-state imaging device according to claim 7, wherein the first material serves as a material for a semiconductor region in the photoelectric conversion unit and also as a material for the protrusions.

9. The solid-state imaging device according to claim 7, wherein the second material includes a film having a negative fixed charge.

10. The solid-state imaging device according to claim 9, wherein the second material includes a first film having a negative fixed charge and a second film different from the first film.

11. The solid-state imaging device according to claim 7, further comprising an element separation portion provided between the photoelectric conversion units adjacent to each other, wherein the second material includes an insulating material which is a material of the element separation portion.

12. The solid-state imaging device according to claim 7, wherein the first material and the second material have different light transmittances or refractive indexes from each other.

13. The solid-state imaging device according to claim 1, further comprising a lens that condenses light and causes the light to fall on the protrusions, and a color filter layer provided between the lens and the protrusions, wherein the shape of the protrusions differs for each type of color transmitted through the color filter layer.

14. The solid-state imaging device according to claim 1, further comprising a wiring layer provided on a surface of the substrate opposite to the light incident surface, and a reflector that is provided between the photoelectric conversion unit and the wiring layer and reflects light from the photoelectric conversion unit.

15. The solid-state imaging device according to claim 14, wherein the surface of the reflector on the photoelectric conversion portion side has a recessed shape.

16. The solid-state imaging device according to claim 1, further comprising a memory unit that is provided between the photoelectric conversion unit and a surface of the substrate opposite to the light incident surface and that holds a charge from the photoelectric conversion unit.

17. The solid-state imaging device according to claim 16, wherein the plurality of protrusions have a concentric annular shape having a central axis at the same position in a plan view, and the memory unit is provided at a position not overlapping the central axis.

18. A solid-state imaging device comprising a lens that condenses light, a photoelectric conversion unit that converts light from the lens into a charge, and a light condensing unit that is provided between the lens and the photoelectric conversion unit and condenses light from the lens on the photoelectric conversion unit.

19. The solid-state imaging device according to claim 18, wherein the photoelectric conversion unit is provided in a substrate, and the light condensing unit condenses light from the lens on the photoelectric conversion unit by a plurality of protrusions provided on a light incident surface of the substrate.

20. A method for manufacturing a solid-state imaging device, comprising: forming a photoelectric conversion unit in the substrate, and forming a plurality of protrusions on a light incident surface of the substrate so that the width of the protrusion becomes smaller as the distance from the center of the plurality of protrusions increases.
